(19) United States
(12) Patent Application Publication
(10) Pub. No.: US 2020/0411343 A1
(43) Pub. Date: Dec. 31, 2020

(54) REAL-TIME MONITORING OF A MULTI-ZONE VERTICAL FURNACE WITH EARLY DETECTION OF A FAILURE OF A HEATING ZONE ELEMENT

(71) Applicant: X-FAB Semiconductor Foundries GmbH, Erfurt (DE)

(72) Inventor: Sven GRUBER, Weinboehla (DE)

(21) Appl. No.: 16/649,833

(22) PCT Filed: Sep. 25, 2018
(86) PCT No.: PCT/IB2018/057414

§ 371 Date: Sep. 8, 2020

(30) Foreign Application Priority Data
Sep. 25, 2017 (DE) 10 2017 122 205.7
Jan. 18, 2018 (DE) 10 2018 101 010.9

(51) Int. Cl. H01L 21/67; G01R 27/14; F27B 17/00

(52) U.S. Cl. CPC H01L 21/67248; H01L 21/67109; F27D 2019/0025; F27B 17/0025; G01R 27/14

(57) ABSTRACT

Real-time monitoring of a multi-zone vertical furnace with early detection of a failure of a heating zone element is disclosed. For example, a continuously provided measurement of a resistance value (R₁) of a resistance (1) in at least one heating zone (1′) of several heating zones (1′, 2′, 3′, 4′, 5′) takes place in the thermal device (100), each currently measured value (R₁(i)) of the resistance (1) in the related heating zone (1′) is compared with a previously measured value (R₁(i−1)) of the same resistance (1), and a warning or an alarm (90) for the thermal device (100) is generated when a deviation (310, ΔR₁) is detected by a comparison of the two resistance values from the same heating zone (1′) before a failure of a complete heating zone (1) in the thermal device (100) takes place.

The invention relates to a real-time monitoring of heating elements in a multi-zone vertical furnace, such as the Five-Zone-Furnice Alpha8SE by TEL (Tokyo Electron Limited). The high temperature derives from values higher than 500′C prevailing in the thermal device (claim 1) during active operation; cf. Equipment Datasheet, TEL-Alpha-8SE, August 2004, downloaded on Sep. 23, 2017 . . . www.agsemiconductor.com/files/LM28.pdf.

With regard to wafers, US 2010/14749 (Turlure, STM) refers to a wafer furnace (there page 10, column 3, par. 45, 46) in which a temperature sensor 29 is arranged. If the measured temperature exceeds a threshold value that is given by camera 26 located there, the furnace becomes too hot or is too hot and the camera that serves to position wafers might get damaged. A detection of a fault of the wafer furnace is not intended here (and is not possible).

US 2009/237102 A1 (Lou, Star Technologies) describes a heating system for semiconductors and has a temperature control for the control of the furnace temperature. For this purpose, test signals for the semiconductors are provided in the furnace.

DE 39 10 676 A1 (Pierburg, Loesing) in a remote field refers to a measuring device for air-mass flow in internal-combustion engines, which means vehicles. Operational measurement errors, for example due to deposits or ageing processes are to be avoided. At regular intervals measurements are carried out whose result is compared with a result of an induced correction, cf. column 5 there, lines 40 to 51 or column 1 starting from line 52 or, for ohmic resistances, column 4, line 12 ff. In this case, the invention relates to a monitoring of individual heating zones (containing at least one heating element) with regard to premature wear and thus also of all heating zones together. Including several installations, each having several heating zones.

Currently, there is no possibility to recognize a premature failure of a heating zone. Thus, there is a high risk for a wafer loss of 150 wafers per installation. The Japanese installation manufacturer Tokyo Electron (TEL) only has a method for the recognition of an actual failure of a heating zone. This kind of thermal monitoring, recognizing the defect due to a drop of temperature and generating a temperature alarm at the installation is also offered by other manufacturers.

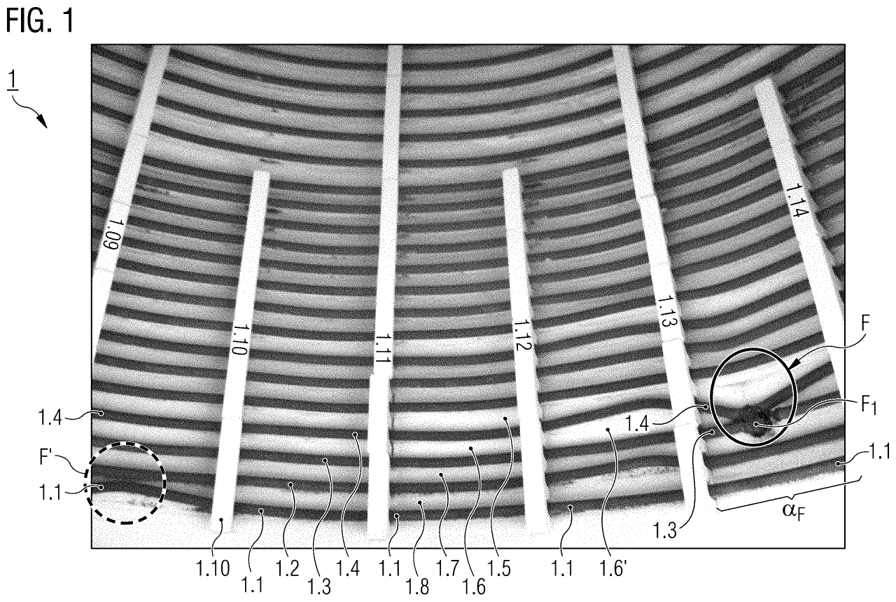

The heating system of TEL is a vertical 5-zone heater, operated in the range of 600° to 1,150° C. Due to the vertical arrangement and the high temperatures, the individual coils (windings), arranged planarly, become deformed over time and a contact of two adjacent sections of a winding within one zone (see FIG. 1) may occur. Due to this effect, the resistance decreases by several percent and after a certain time a breakage of the winding may occur at this position.

Up to now there is no possibility to detect a heating failure of the five zones prematurely when the installation is in standby mode or in process. In the past, a number of events of a failure occurred. These incidents occurred on the one hand during the process by means of the generation of a temperature alarm (leading to a process interruption), but also in standby mode such an interruption occurred.

In the case of a failure in standby mode, the process of tempering the wafers could be started nonetheless since no alarm at the installation was generated. The process, preloaded with valuable wafers, started and was then cancelled by a temperature alarm.

Each process cancellation provokes a loss of production of at least 150 wafers (300,000 EUR damage costs) of an entire lot (or charge) and a long non-availability of the installation of approximately 12 days.

Starting from the above-explained state of the art, the present invention is based on the following technical problem . . . . The aim of the invention is to avoid wafer losses with values of up to 150,000 EUR per charge. In addition, an unplanned failure of the thermal device is to be avoided and a better planning reliability of resources shall result.

The claimed invention (claim 1 or claim 18 or claim 20) recognizes wear at an early stage (contact of the elements or areas of the heating coil or the occurrence of a punctual conductive area in the heating coil) in order to minimize the wafer loss or avoid it at all and offer a better planning reliability concerning staff and material.

According to the invention, for this purpose a continuous measurement of the resistance (obtained from measurements of voltage and current) on each heating zone takes place. The current value of the resistance is compared with the previous value. Already in the event of a small deviation of the resistance value, an alarm (a warning) is generated for the installation, temporally long before a failure of an entire heating coil.

The invention uses the effect that a real-time recording in the individual heating zones is implemented continuously and thus a contact within the coil is recognized before an irrevocable breakage of the coil occurs. Those are the expected error (already given as alarm message) and the real error (coming as breakage of the coil).

A record of an expected error before the actual operation in the so-called standby mode is possible as well (claim 5). If in this case the expectation of an error occurs, there is no switching on.

The benefits resulting from the invention in particular are that the risk of a wafer loss can be minimized clearly by already stopping the installation when an imminent failure is detected and for example the five-zone heater may be exchanged preventively or even individual heating zones may be renewed, or the thermal installation is not started at all before a repair has not taken place.

The claimed screen display allows a monitoring of various thermal devices in a clearly arranged way and allows the user an immediate identification of the system status, even when a great plurality of installations or resistances included therein have to be monitored.

The screen display is also (efficiently) suited for implementing the method according to one of the claims 1 to 17.

It has a configuration window area for the display of technical parameters of the thermal devices and a measuring and recording window area for the display of technical measuring values or calculated values of one of the thermal devices calculated by technical measuring values, preferably several independent last window areas, of which in each case one is assigned to only one thermal device. Thus, several installations are represented on the screen individually but not mixed with each other.

The respective dependent claims are included herein.

For concrete examples of the invention, reference is made to the figures (also illustrations), however, these examples are not to be understood in such a way that they contain compulsory elements that have to be included in the main claims in this respect or seem to be necessary there. This, however, does not mean that the examples do not contain any disclosure suitable for a supplement of the claims.

Even if the term “in particular” or “for example” does not occur at every point or in every sentence, the skilled reader may please understand the examples given below concerning the claimed invention as examples with exemplary elements, values and functions.

Elements not described must not be understood in such a way that their existence is disclaimed. If only one example of an element, a value or a function is disclosed, this may nonetheless be modified in an obvious way from skilled person in the field.

For examples of the invention, reference is made to the figures (also illustrations). They describe the following . . . .

FIG. 1 Example of a contact of a coil in a heating zone.

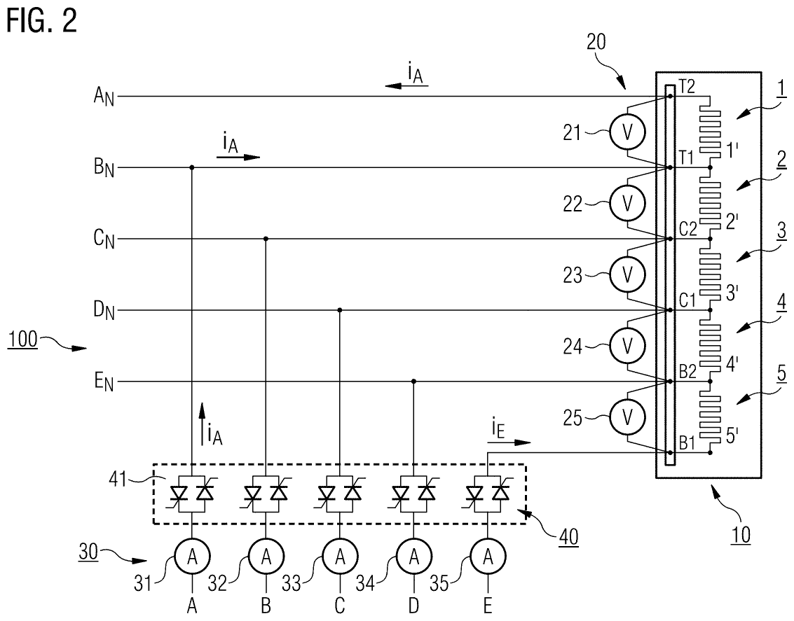

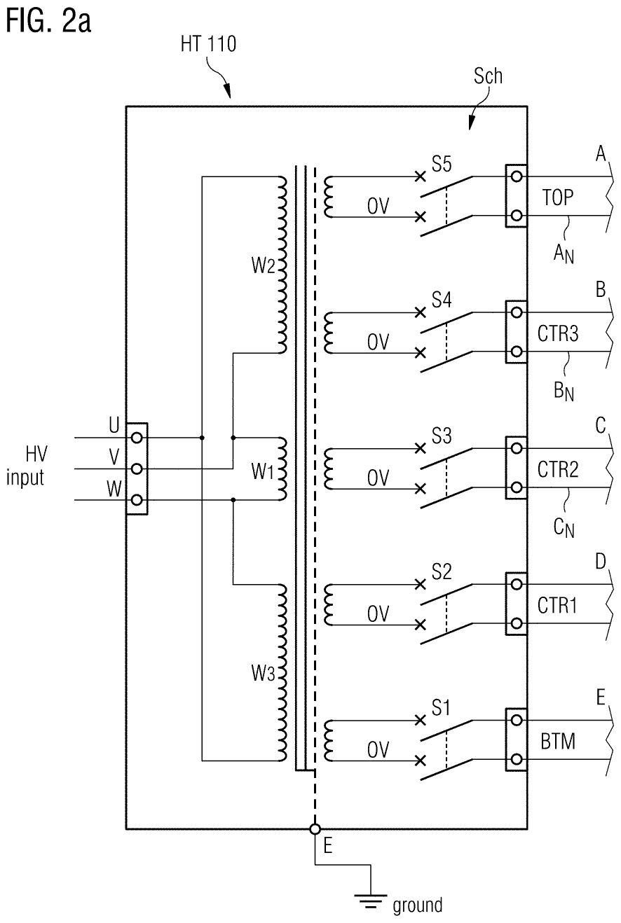

FIG. 2 Schematic diagram of the heating (in the installation 10).

FIG. 2a Circuit diagram of the heating at the high voltage side.

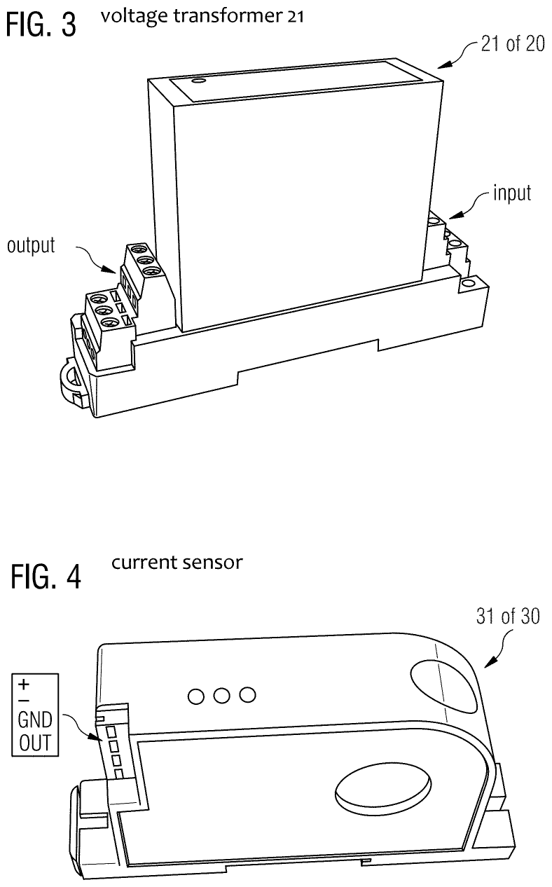

FIG. 3 Example of a voltage transformer.

FIG. 4 Example of a current sensor.

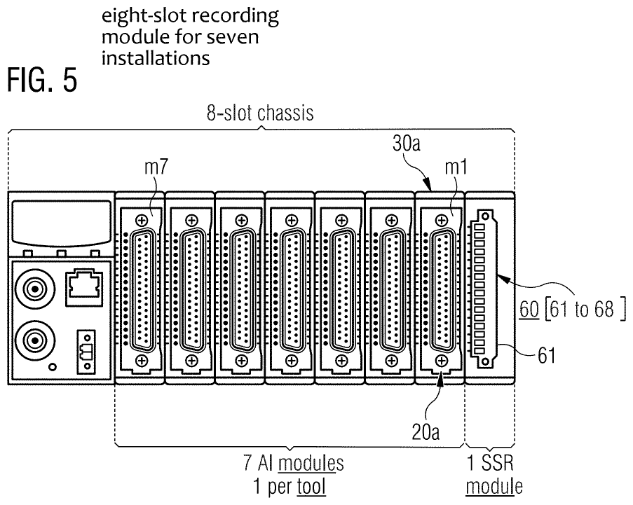

FIG. 5 Eight-slot recording module for seven installations.

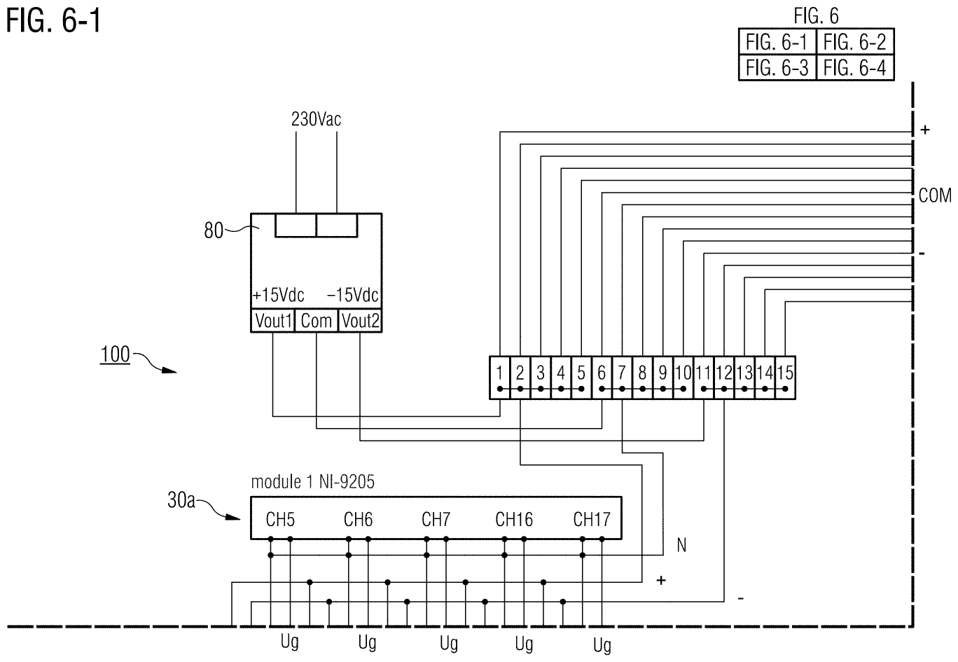

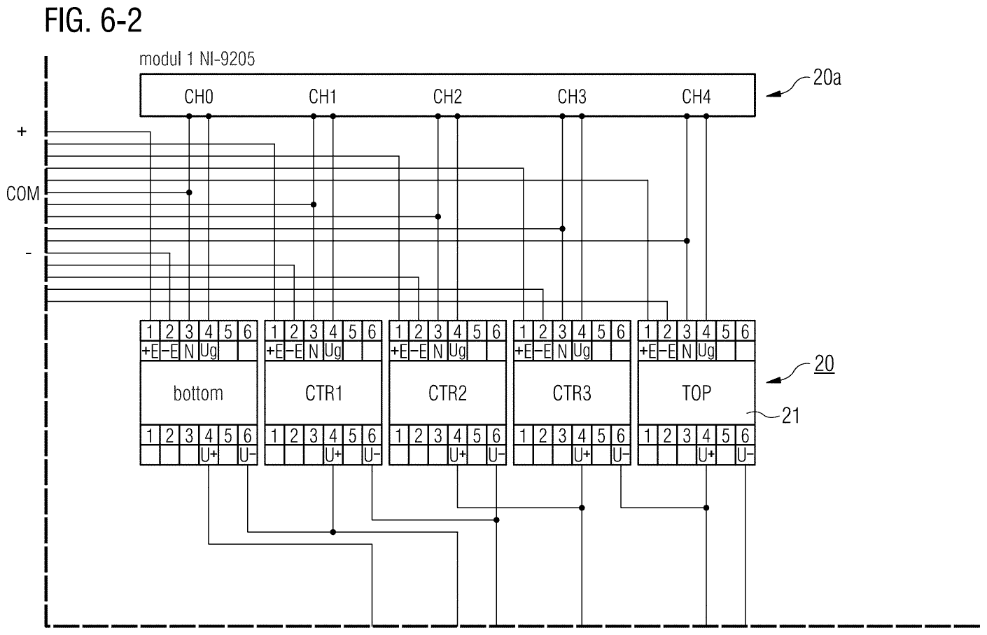

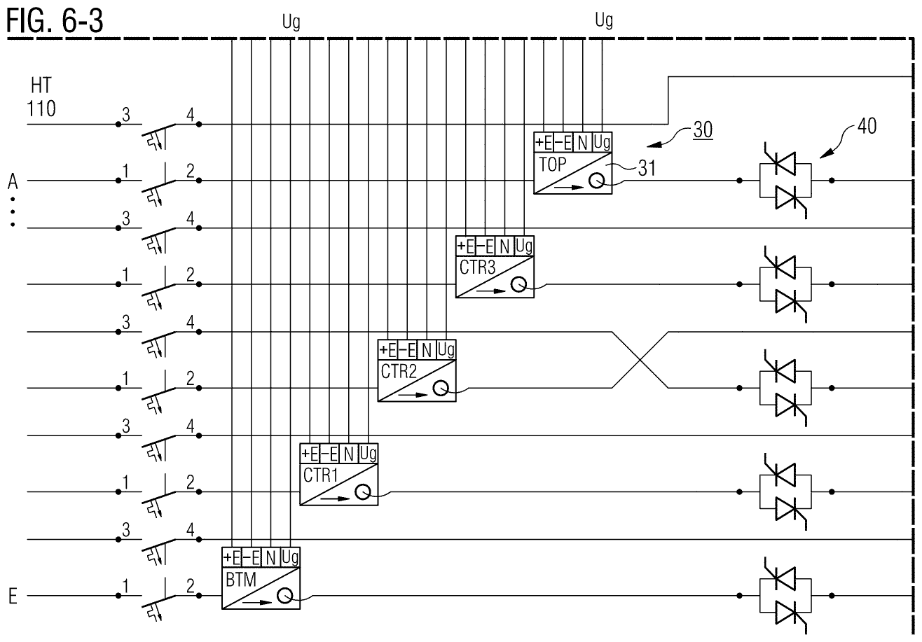

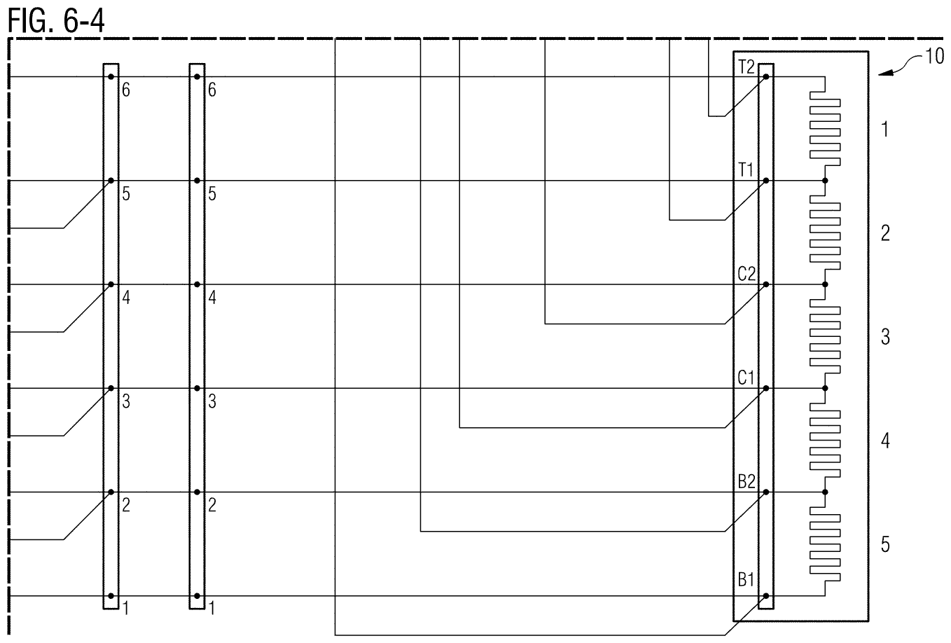

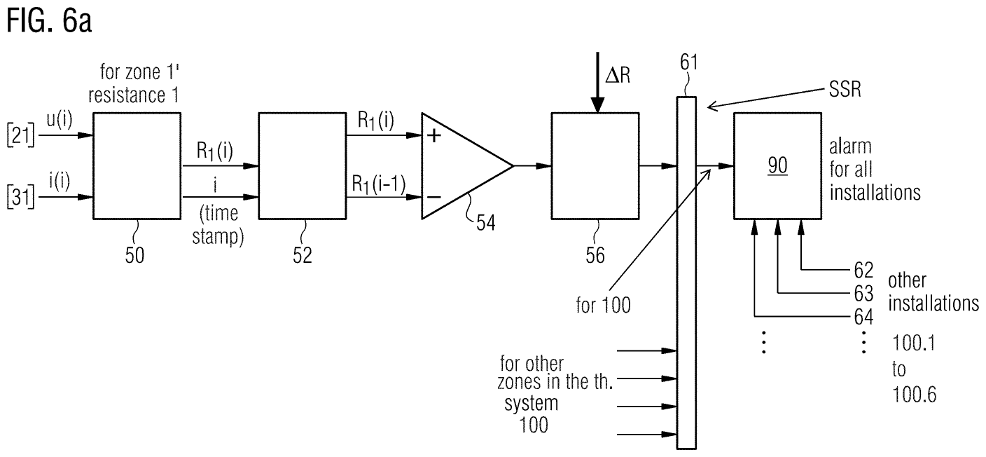

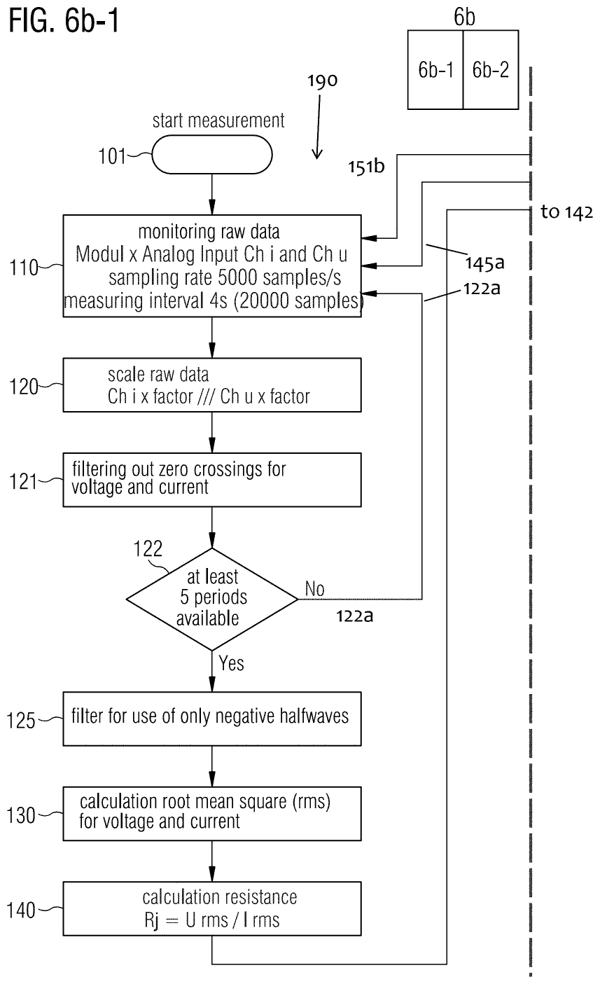

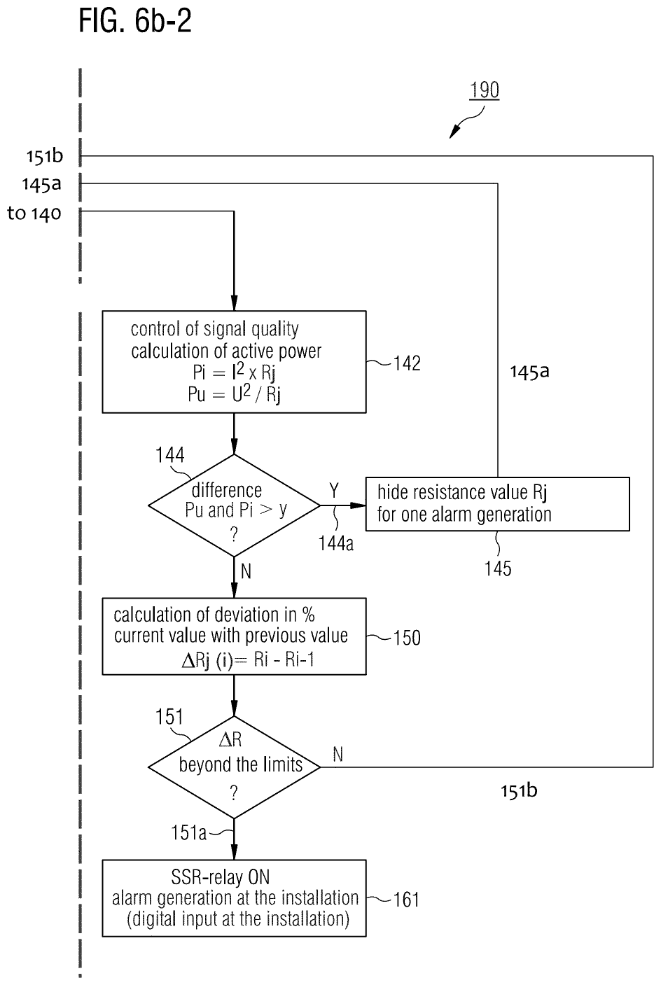

FIG. 6 Electric diagram of the installation in an example.

FIG. 6a Block diagram of the resistance measurement and installation monitoring.

FIG. 6b Plan of procedure for a program-technical solution of the resistance measurement and installation monitoring.

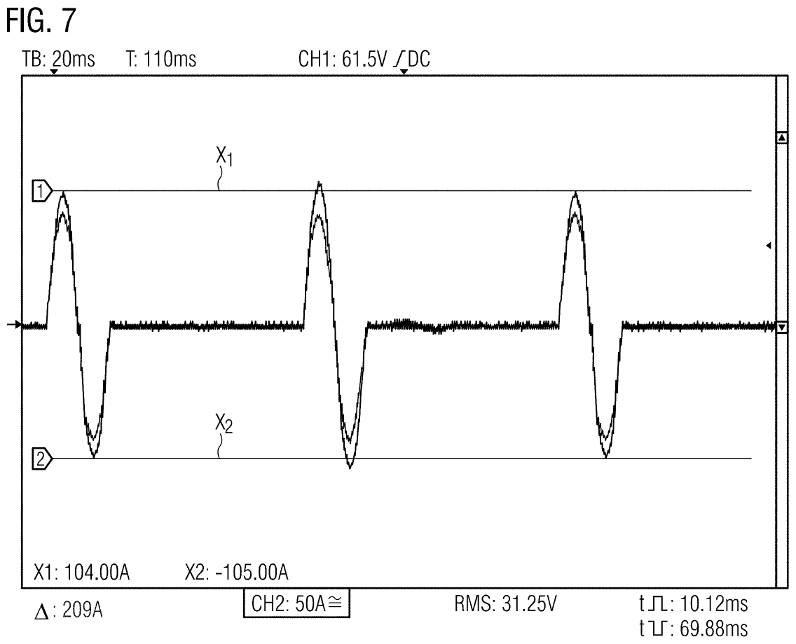

FIG. 7 Measurement of voltage and current by means of oscilloscope.

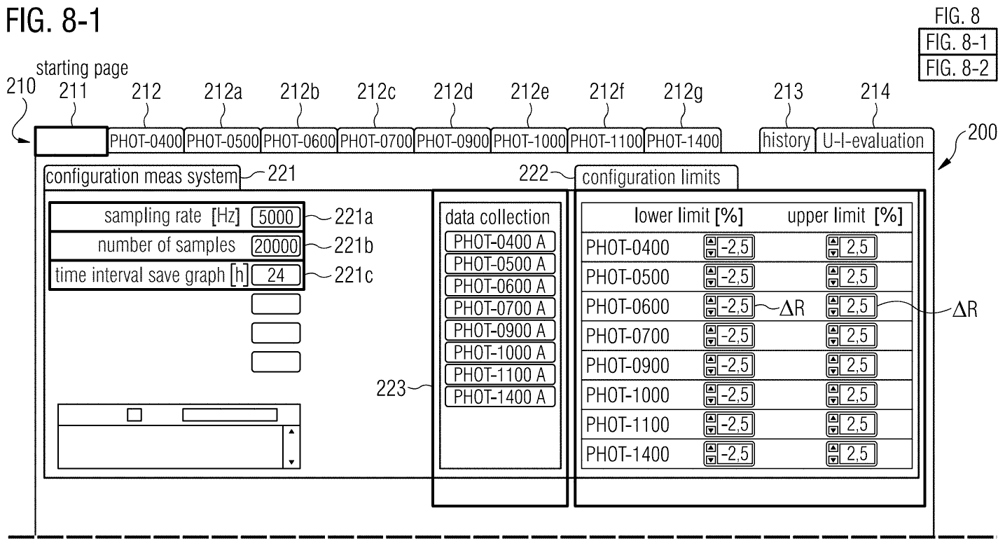

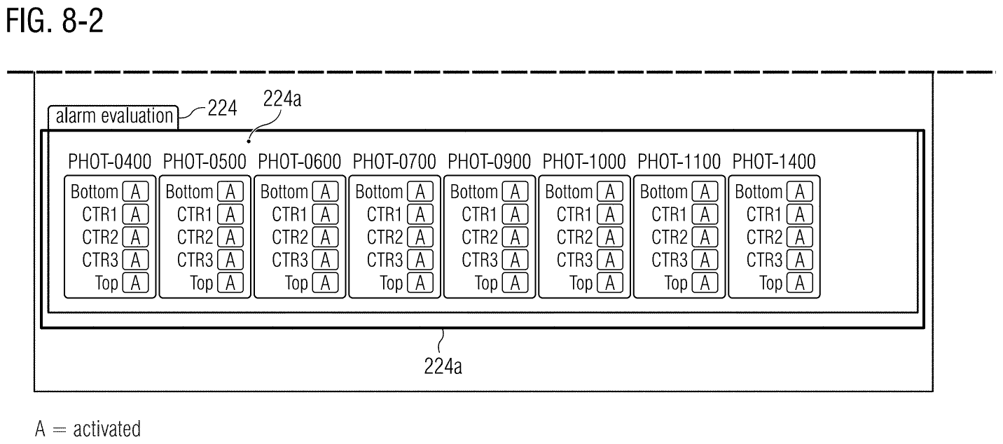

FIG. 8 Software register as screen display, starting page for a USER interface.

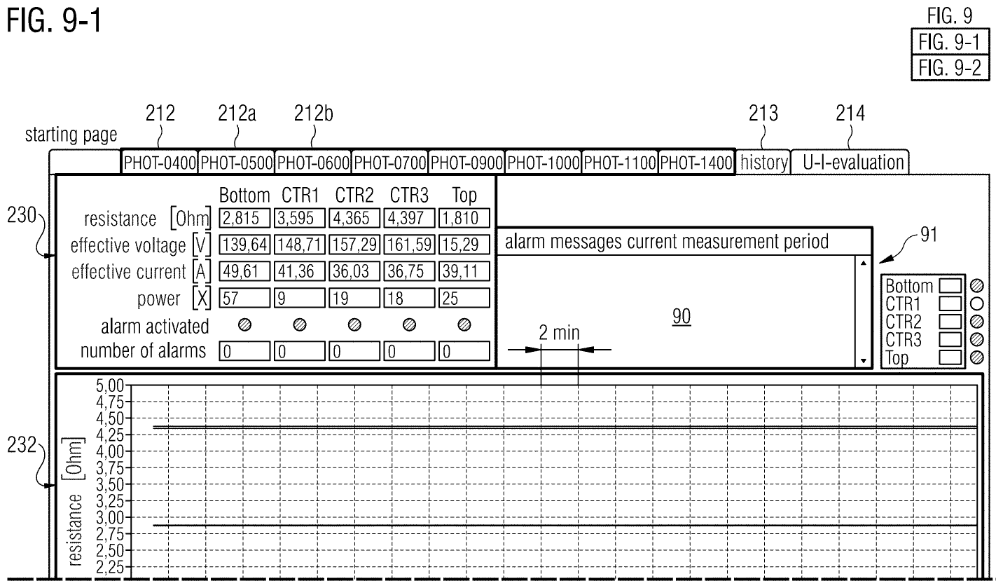

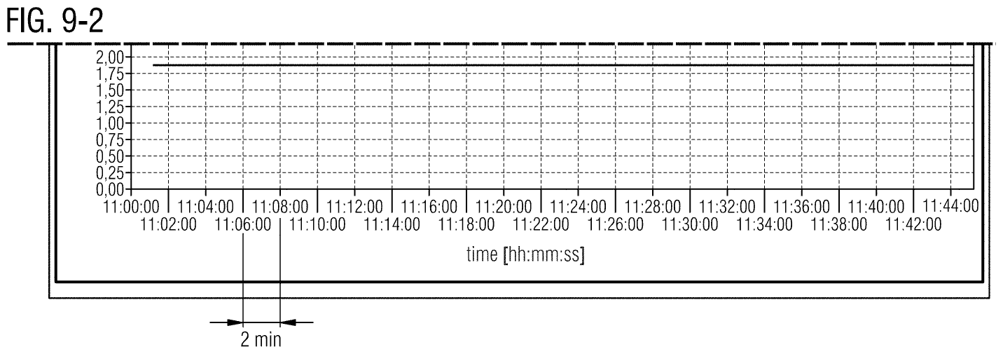

FIG. 9 Software register as screen display, installation pages as USER interface.

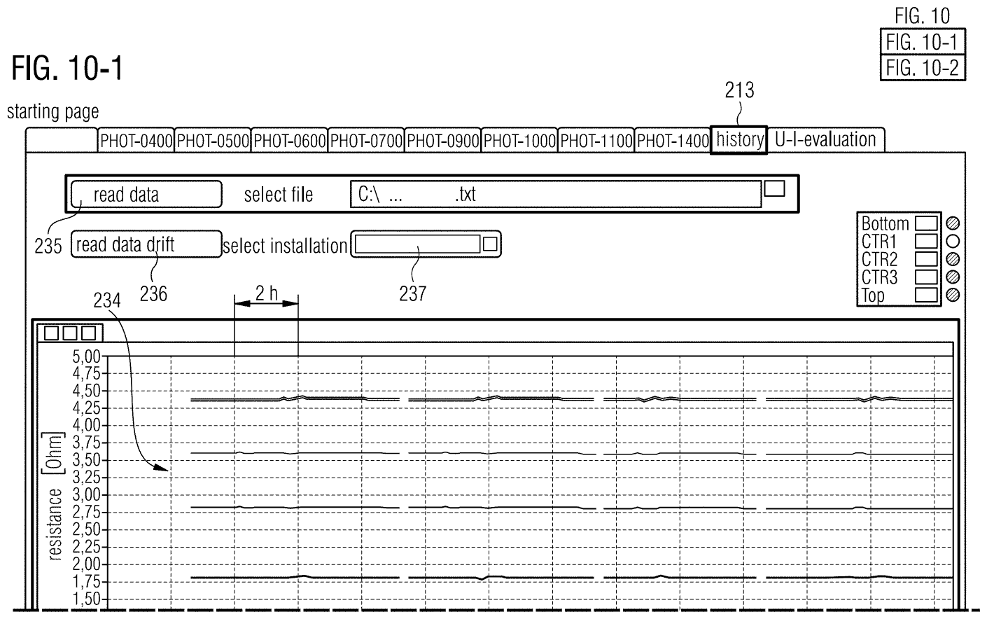

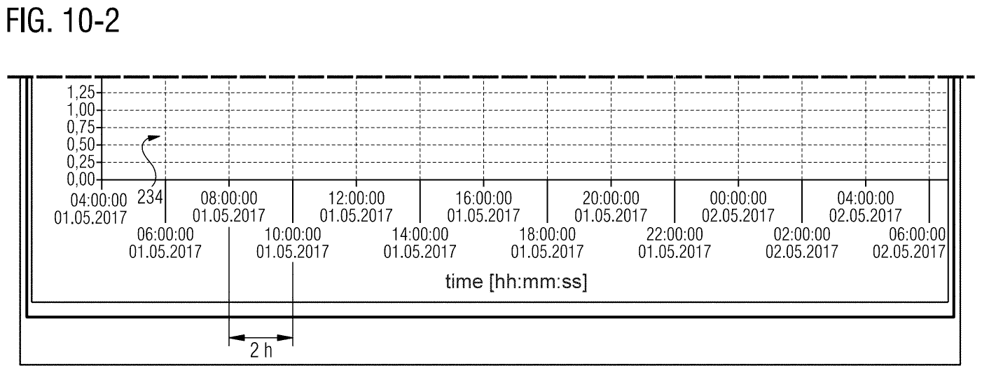

FIG. 10 Software register as screen display, history-data-evaluation.

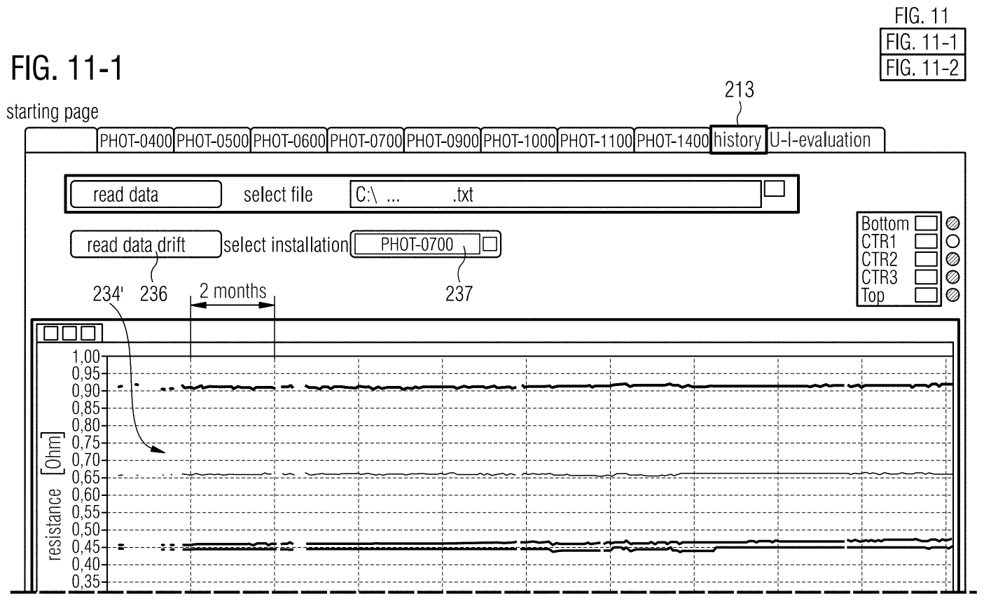

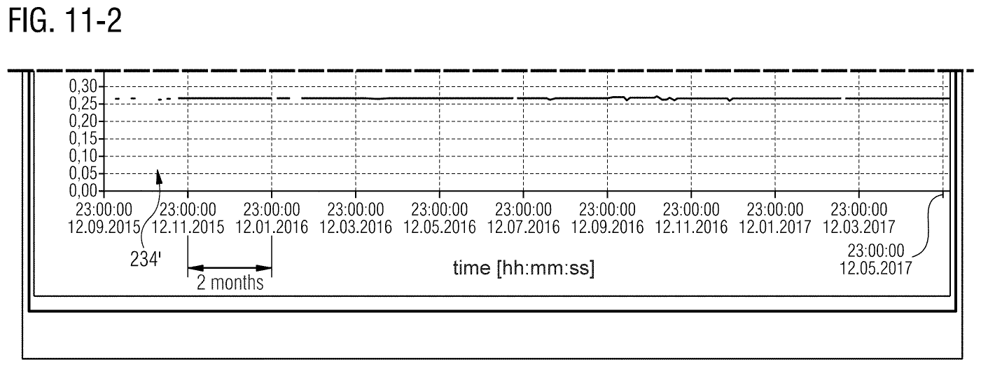

FIG. 11 Software register as screen display, reading history-data-drift.

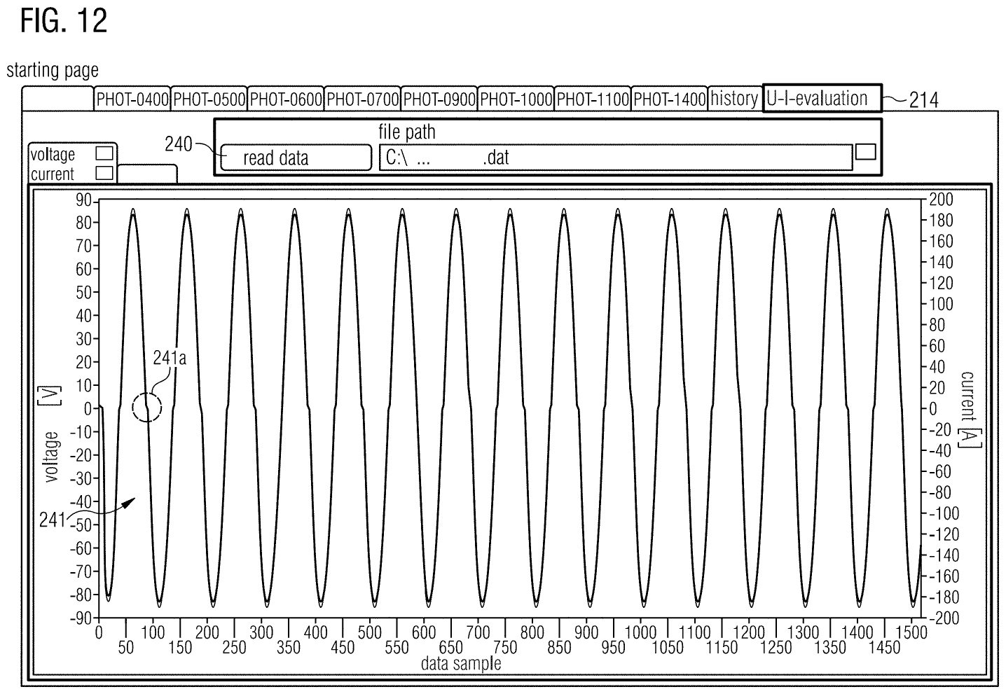

FIG. 12 Software register as screen display, UI-evaluation.

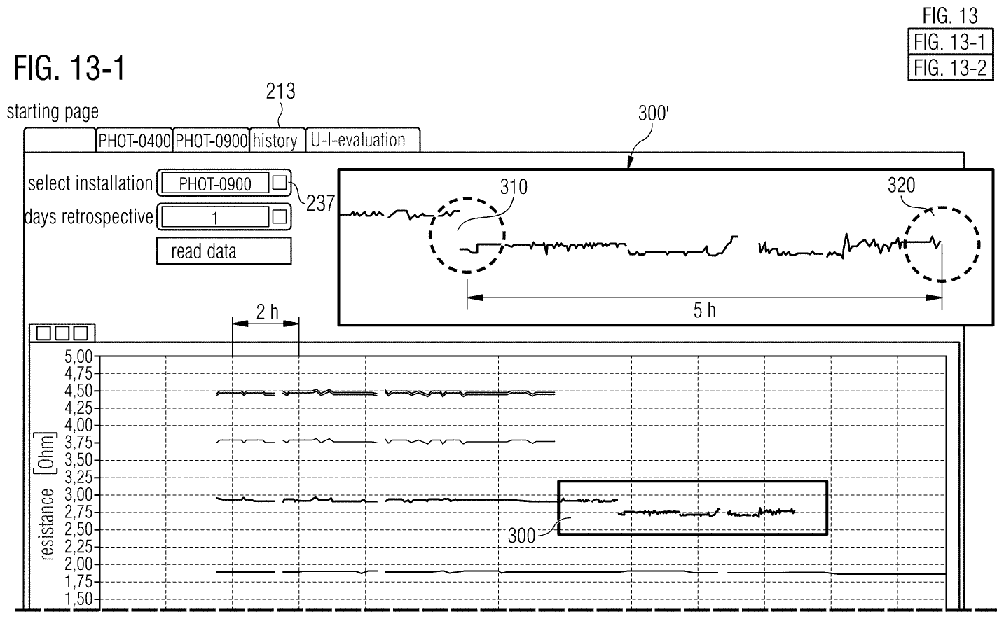

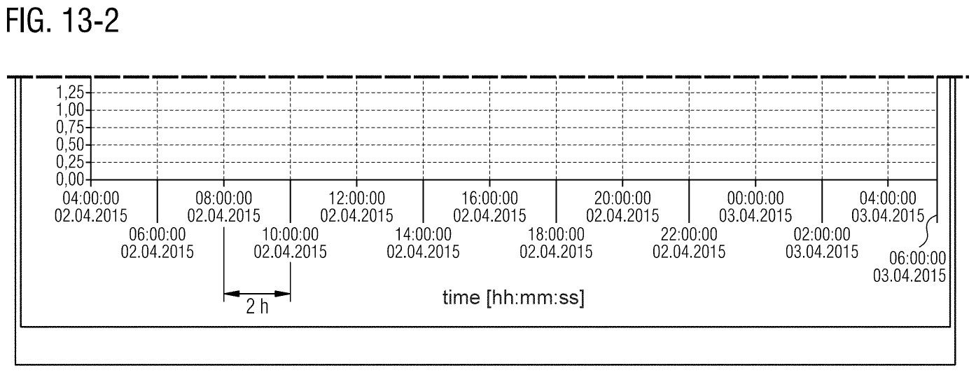

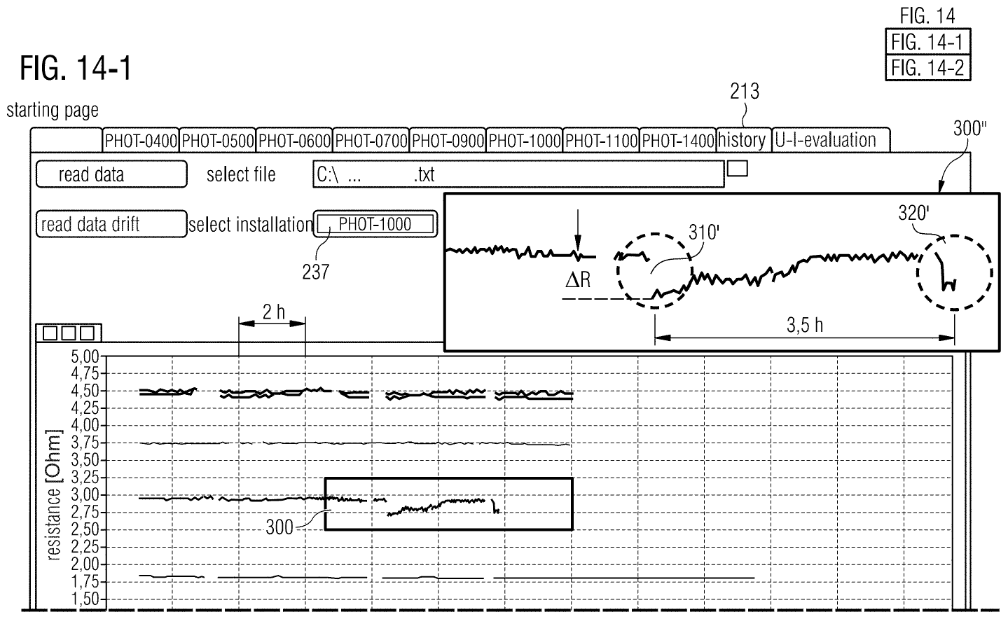

FIG. 13 Premature detection of a coil-contact-event 1.

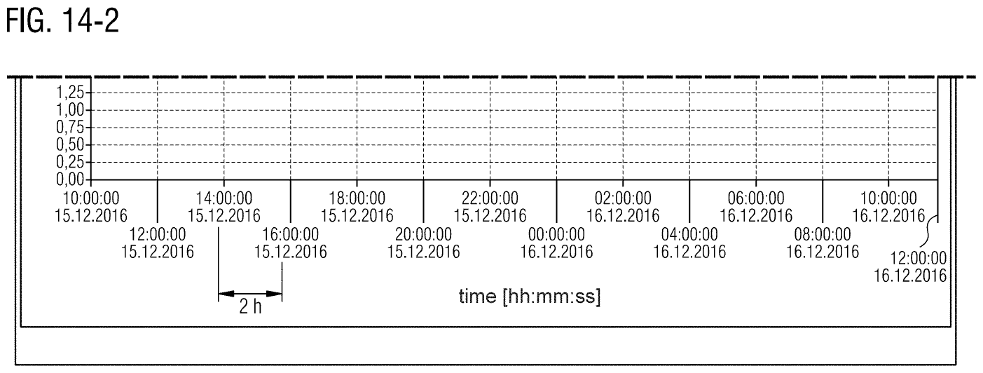

FIG. 14 Premature detection of a coil-contact-event 2.

A close-up view of a coil, which means a resistance as heating coil in coiled, planar shape is illustrated in FIG. 1. Here, a coil contact F₁ is shown in the area of a developing coil damage F (within circle), caused by contact of two adjacent heating wire areas (shown in black and dark).

Before such damage occurs, the invention described in here, in particular the herein described exemplary embodiments, shall be able to predict this damage as arising damage.

The center of the coil is not shown, it is to be assumed above, approximately in double height of the illustration. The section is shown on a bottom edge region and such a coil is explained on the basis of the resistance 1 in the heating zone 1′. The heating wire is one piece end-to-end, coiling helically around a center to the outside.

Radially directed bars, shown bright in FIG. 1, stabilize the position of this heating wire, shown dark. Between two respective, radially adjacent sections of the heating wire (shown dark in the illustration), there is insulating material (bright in the illustration). In the edge region some individual numbered sections of this heating wire can be seen. The sections 1.4, 1.3, 1.2 and 1.1 are adjacent sections of the heating wire, which means the winding in total. The outermost wire or cable section 1.1 leads through under all bars 1 to 1.1. It starts left in the illustration, beneath bar 1.10, continues to the right and arrives at bar 1.11, 1.12, then to the following bars 1.13 and 1.14.

The bars have approximately the same circumferential space angle, but are not equally long in their longitudinal extension (in radial direction), but are alternately shorter and longer, as shown in the illustration.

The insulating zone 1.6 lies on the inner edge of section 1.3. The bars lean on insulating zones (shown brighter) located between the heating wire sections. Still further to the inside lies the next insulating zone 1.5, adjacent at the inside to section 1.4 of the heating wire. The above described wire sections 1.4, 1.3, 1.2 and 1.1 continue in the following section on the right side between the radial bars 1.12 and 1.13.

In this section of intermediate bars, it can be seen that the insulation 1.6 thickens clearly (section 1.6′), which means that the sections 1.3 and 1.4 of the heating coil move further away from each other and then, in the following section of intermediate bars, marked with α_{F}, move clearly to the outside regarding section 1.4, so far that in the encircled fault area F there is a contact of the two cable sections 1.3 and 1.4 in the section of intermediate bars α_{F}, marked with F1.

This local case of contact causing a short circuit of a circumferential coil (approx. 360) leads to a case of failure. This case of failure may have the effect that the entire heating coil 1 fails if it comes to an excessive overheating at the point F₁, that may even lead to a line breakage.

This can be seen in the dashed area F′. It is a (upcoming) further case of failure concerning the wire sections 1.1 and 1.2.

### Exemplary Embodiments of the Hardware

A schematic diagram of the assembly is illustrated in FIG. 2.

A voltage at each resistance is measured by means of a respective optically potentially isolated voltage transformer 20 (from FIG. 3) directly at each heating zone 1 to 5. A current detection 30 of each zone 1 to 5 is realized in each case via a contactless Hall current sensor (from FIG. 4) between phase A to E and SCR-unit 40 (thyristorblock or heating control).

Due to the contactless measurements, the heating zones are not influenced in the case of a sensor failure. Both sensortypes (current sensors 30, voltage sensors 20) use a ±15V direct voltage as potentially isolated supply voltage.

For evaluation of the current and voltage signals, a 8-slot housing is used for modules m1 to m7, wherein each module provides an analog detection range 30a for current and an analog detection range 20a for voltage. The eight-slot-housing of the exemplary assembly is a NI-cDAQ 9188 of National Instruments. It accommodates the 7 analog input modules (16 analog inputs per module) and a solid-state-relay module 60 with eight SSR-relays (see FIG. 5).

With this hardware, seven heaters with five zones each from different installations can be monitored simultaneously (which means seven heating installations 10 from FIG. 2 with at least five zones each).

Via the relays 60 it is possible to establish a connection to a respective thermal installation 10 to generate an alarm 90.

The electrical wiring of the hardware is shown according to FIG. 6 (example of an entire installation 100). Each installation has an electric control box where the voltage transformers 20 and the power supply 80 with ±15V (DCV) are implemented.

To avoid interferences, anti-interference capacitors may be installed at the current sensors 30, since these are mounted in direct vicinity of power transformers in the installation. In addition, shielded multicore cables may be used.

For picking up voltages, non-flammable cables may be used.

The entire installation 100, above shown summarily, will be explained in more detail in the individual components using reference signs.

Above, the current sensors 30 were summarily mentioned, shown in FIG. 2 before the thyristorblock 40. In the example for the five zones 1′, 2′, 3′, 4′ and 5′ of the thermal installation 10, those are five bidirectional thyristors that may also be connected as Triac, in general they were previously described as heater control. Their control is in accordance with standard practice and is not to be mentioned in detail here. However, the effect will be explained.

The five zones 1′ to 5′ are shown in the thermal installation 10, there they are indicated with five resistances 1 to 5, each resistance located in a zone. The resistances have the same name as the zones, which means resistance 1 in zone 1′, resistance 2 in zone 2′, resistance 3 in zone 3′, resistance 4 in zone 4′ and resistance 5 in zone 5′. Since in the example these resistances are connected in sequence, one can speak of an upper resistance (top) and a lower resistance (bottom). They are arranged accordingly in heater 10.

The voltages at the resistances, which means each voltage at each resistance, are determined by means of the abovementioned voltage sensors 20, here a voltage sensor 21 in the heating zone 1′ at the resistance 1 is provided, all further voltage sensors 22, 23, 24 and 25 correspond to the heating zones 2′, 3′, 4′ and 5′ or the corresponding resistances 2, 3, 4 and 5 respectively.

Each thyristor in the thyristorblock 40, respectively a corresponding reverse pair of thyristors, for example 41, controls a resistance, in the example resistance 1 (the heating coil 1) in the heating zone 1′. Here, a current i_{A} is drawn in, flowing from the specified potential-free secondary voltage load A via the current measurement 31, the bidirectionally connected thyristors 41, the corresponding line to B_{N}, then into the heating zone 1′ through resistance 1 and in the end out via the connection cable A_{N}. This current is an alternating current, deriving from a voltage, explained in the following with the aid of FIG. 2a.

This voltage A has a phase and a neutral conductor A_{N}, here named “top”. They derive from a winding at a common transformer core, windings of which there are five in the example. These windings and their outputs, each having phase and neutral conductor, in each case potential-free, are named A, B, C, D and E. They are connected to the respective phase inputs A, B, C, D and E of the thyristor block 40 (in each case the phase) and the respective neutral conductor A_{N}, B_{N}, C_{N} etc. (is connected) to the respective neutral conductor A_{N}, B_{N}, C_{N} etc. in FIG. 2.

The heating transformer 110 has a primary high input voltage that may lie between 300V and 600V, preferably 380V nominal alternating voltage. The respective input circuit consisting of three phases U, V and W is connected to three windings W1, W2 and W3 in a delta connection, that are coiled on a common core. This transformer core has five potential-free secondary windings on the secondary side, matching the amount of the heating zones in the thermal installation 10.

Each secondary winding powers a heating zone and since the heating zones with their resistances are connected in sequence, an individual heating of the respective zone can take place also with each winding via the thyristor block 40 and the therein existing bidirectional thyristors.

The switches shown in FIG. 2a switch on the heating zones and their supply voltage, here they are summarily called “Sch”, and are also shown in FIG. 6 at the lower left. The voltages shown there correspond to the voltages A to E (from top to bottom).

The current levels of the supply of the heating transformer 110 are adjusted to the current tolerability of the resistances 1 to 5, they amount to between 30 A and 55 A. The voltages of the secondary windings of the heating transformer 110 are adjusted accordingly as well and amount to 1.8Ω to 4.5Ω in the average temperature range and between 0.25Ω and 0.9Ω in the high temperature range.

The currents may reach up to 150 A. The resistances may have a value up to less than 1Ω.

For the coordination of the following explanation, it must once again be made clear, that the heating zone 1′ possesses the resistance 1 (as physical or concrete resistance). It is designed as coil as shown in FIG. 1. Its operational value (here called resistance value) amounts to R₁.

The heating zone 1′ in this example is the upper heating zone “Top” and has the voltage measurement at the physical resistance 1 with the sensor 21. In the example shown, the current i_{A} in this resistance 1 flows with the resistance value R₁. The resistance value, determined by means of the voltage measurement 21 and the current measurement 31, amounts to calculated R₁, wherein in a continuous measurement several resistance values are measured and calculated, since the ohmic value of the resistance 1 changes and thus several measured resistance values are produced as i-th measuring values of the running measurement, which means R₁(i), R₁(i+1), wherein i=1 to n. n being a multiple of the sampling time (more exactly . . . of the sampling interval).

The same applies to the heating zone 2′ with the physical resistance 2 and its ohmic resistance value R₂, continuously over the time as R₂(i), wherein i=1 to n. In the same way, the explanation is to be applied to the other three resistances 3, 4 and 5 in FIG. 2, with the appropriate indexes 3, 4 or 5 respectively.

Physically, the voltage transformers 20 are shown in FIG. 3, as attachable housing (on a snap-on bar). They have input connectors and output connectors that are potential-free.

For the current sensors 30, FIG. 4 shows an example for a current sensor 31, measuring current potential-free, that is supplied to for example the bipolar thyristor 41 from thyristorblock 40.

Several current sensors are used, in the example they are five, according to the five zones for an installation 10. If more installations are used, there are more current sensors accordingly.

Since the amount of current sensors 30 and the voltage sensors 20 may become very large, input modules are provided for the evaluation of the measured signals of current and voltage, in the example those of FIG. 5 as 8-slot housing 30a (for current), and 20a (for voltage), shown in FIG. 6. Here, there are seven installations with five heating zones each in this example.

Since 16 analog inputs are available per module, also more heating zones per module can be included than have been connected in this example. Here, five inputs for current signals and five inputs for voltage signals are used, in the example of FIG. 6 they are the functional areas 30a (for current) and 20a (for voltage) in a physical module m1. Thus, a thermal device 10 can be assigned to a module.

In FIG. 6a a schematic block diagram (as circuit) is shown as it can be realized for a zone and a resistance contained therein.

If several zones are monitored, this schema can also be transferred to several zones or be regarded multidimensionally in such a way that each function block 50, 52, . . . is as frequent as there are resistances to be measured in a thermal installation, i.e. either in a thermal installation 10 or also across installations, if several installations, for example seven installations with five heating zones each, are monitored.

Here, the monitoring for zone 1′ in the thermal installation 10 shall be explained with FIG. 6a.

By means of the voltage measuring 21 and by means of the current measuring 31, a temporarily applied measuring value is recorded in each case, occurring at the moment i (i is a consecutive variable of the digital record and may also be called time stamp). In the case of alternating current, those are preferably effective values and not momentary values. Both measured signals, the voltage and the current at the moment i are added to the processing unit 50 for the calculation of a resistance value R₁(i), belonging to a time value as time stamp i.

This measurement and this calculation takes place continuously during operation of the installation 10 and the continuously determined resistance values R₁(i) are saved in the temporary memory 52. This temporary memory 52 outputs the actual value and the preceding value, especially the directly preceding value and feeds a comparator or a subtractor 54.

The two resistance values R₁(i) and R₁(i−1) are subtracted or compared in their value and the comparison result, especially the difference ΔR₁(i) of those two values is outputted. In general, those are the resistance-differences ΔRⱼ(i), at j=1 to m, wherein m=5 stands for five heating zones in the example.

The output of the difference ΔRⱼ(i) takes place at a threshold value switch 56, which responds when a preset differential value ΔR is exceeded (also referred to as window with upper limit and lower limit) and the threshold value switch 56 gives a signal to one 61 of the SSR relays 60, that generates an alarm signal 90. The various SSR relays 60 are shown in FIG. 6, one of them, the SSR 61 in this case is active at a heating coil 1 of the first thermal installation 10.

The fed-in deviation ΔR defines the response sensitivity and indicates, whether a failure F, caused by a contact of two adjacent heating wire sections in the area F₁ is imminent or already arising. Thus, the alarm 90 due to the recognized failure is generated, even far before a breakdown of an entire heating coil 1, that was used in this example in FIG. 6a and in FIG. 1.

With the measurement and the calculation of a continuous resistance value, the contact within a coil can be detected at an early stage, before there is a final breakage of a coil or there finally is a breakage of a coil.

Assigned measures are possible, for example the installation is not switched on before a repair was carried out. The installation can also be already stopped before a failure occurs and the entire heating device consisting of all available, especially five zones may be renewed. Another possibility is to block the starting of the thermal installation, when the monitoring took place in standby-mode and the arising actual failure (the imminent breakage of the coil) is recognized (as “case of failure” of the monitoring, generating the alarm).

Software Realization (Program-Technical Realization)

Measuring data acquisition and monitoring can also be made programmatically as explained in FIG. 6b. The programmed plan of procedure is 100. It works with real measuring values taken from an operational procedure (like a process calculator assigned to a technical field, not processing abstract data and thus is no “data processing system as such”).

The recording of current- and voltage signals (i.e. the measuring values) is realized simultaneously with 5,000 values/sec per analog input over all installations 10, programmed function 110. A measuring interval amounts to 4 sec, corresponding to 20,000 values in total per analog input. The entire measuring data packet can be transmitted via a network, for example per Ethernet (not shown) to a software-programmed control system, implementing the function of FIG. 6a, illustrated as switch, or is comprised in the software plan of procedure 190.

Filter and Evaluation

The thyristor control 40 of the installation takes over the temperature control of the individual heating zones. Depending on the power specification (0% to 100%), it connects through several voltage periods for a certain amount of milliseconds (example see FIG. 7).

For the realization of a clean RMS development 130 (Root Mean Square, RMS, effective value) for current and voltage, the zero crossings are filtered out by means of a filter programmed therefore (see FIG. 12 with the steps in the zero crossings from U to I), and only the negative half-waves are used for evaluation, function 125. This is the case because heating zones can influence each other in a positive half-wave depending on performance and thus may cause an unclean signal.

In function 122 it is possible to control, whether a minimum amount of periods is present, for example five periods. If this is not the case, these data are ignored, branch 122a. This is useful in particular, since the power may be less than 3% when the heating installation is cooling down and the amount of raw data (first threshold value) might not be sufficient for an optimal RMS development.

After the RMS development 130, the resistance value of each heating element is determined according to Ohm's law with function 140 and saved with a timestamp in a respective data file, especially a text file.

Subsequently, the power development is controlled with function 142, taken from the determined resistance value with the squared values of voltage and current, to exclude in addition that the signal is disturbed. If the difference in the comparison 144 is higher than a given value (a second threshold value), the measured data (of the measuring interval) of the respective heating zone are ignored as well, branch 144a, function 145.

Alarm Generation

After determination of the process data (no “data as such”), these are evaluated by means of an alarm routine. Therein, the current resistance value is compared to the previous value in function 150. In the case of a deviation beyond a range (e.g. ±2.5% as window ΔR in percent), as third threshold value, after the query 151 via branch 151a, there will be an alarm generation 90 by means of the connection of a SSR-relay of the respective installation with function 161.

Other alarm generations are possible as well, also with the same potential, non-compulsory only by means of a potential-free SSR relay.

In addition, the raw data are saved to allow an analysis of the signal profiles in retrospect. It is also possible to analyze, whether the thyristor-pair for the positive or negative half-wave is defect. This is determined during the procedure and displayed in text form.

Not mentioned up to now is function 120, performing a scaling (or a standardization) of the measured raw data. Thus, the following calculation can use reasonable high values, optionally even the various current values of different zones do not have to be taken into consideration. By means of a standardization, currents between 30 A and 60 A can be tailored in such a way that they have same maximum values or same effective values for the following calculation and error detection. What is important for error detection with function 150, is a deviation in percent.

Thus, the difference resistance ΔR_{absolute} may be referred to the preceding or current measuring value Rⱼ(i) or Rⱼ(i−1), to be expressed as a percentage ΔRᵣₑₗₐₜᵢᵥₑ, thus for the i-th measurement of zone j applies {Rj(i)−Rj(i−1)}/Rj(i). ΔRᵣₑₗₐₜᵢᵥₑ results in function 150.

In the case of a deviation beyond the threshold values, e.g. ±2.5% as window ΔRᵣₑₗₐₜᵢᵥₑ, path 151a is taken during the process, otherwise branch 151b, leading back to function 110, such as the branching-off return paths 122a and 145a, resulting from unattained threshold values.

The various included threshold values shall be pointed out once again. They serve to verify a result that is not just assumed to be an alarm error via 151, 151a and the alarm generation 161, but can undergo a number of plausibility checks, whether it is a true error (in the sense of an expected real error), not only an unfortunate measuring value or a disturbance variable.
(a) The number of periods in query 122 ensures that there are enough measuring results. Since the thyristor control 40 works with a pulse package control as assumed in this example, this means that it always lets pass a complete sinus wave and blocks one or several sinus waves, in the case of low powers, e.g. smaller than 3%, many complete waves of 360° can be blanked and only one or few complete waves are connected through, for example one complete wave is connected through, and five complete waves are paused (blanked). In the case of higher currents, for example eight complete waves are connected through and two complete waves are paused. The latter possibility would support query 122 and mean that there are sufficient measuring values for a calculation of the effective values. This is a first control step, here called “first threshold value”.
(b) A second threshold value lies in the control of the active power by means of current and voltage. If the resistance in function 140 has been calculated, the active power released at the installation or at the zone can be calculated with it, i.e. by means of voltage or current respectively. Both calculated process values of the active power are available and help to recognize errors. This shall be named as second threshold value which is not a real threshold value but only a threshold or switching threshold that shall prevent that failures are passed on or failures are caused as false alarms.
(c) A third threshold value lies in query 151. Here, a deviation minimum that has to be accomplished, is assigned to the to-be-recorded-difference of the measured and the previously measured resistance value (or a resistance value measured still earlier), in order to cause an error by means of alarm routine 151, 151a and 161 as real alarm.

One, two of them, or all three threshold values help to improve security and reliability of the error detection and to prevent false alarms to the greatest possible extent up to almost completely. In this context, it should be remembered that a shut-down of the installation is associated with the risk to lose the wavers contained therein. That is why an early detection shall be possible, but at the same time, also a reliable detection shall be obtained. In control technology it is well known that a system, the more sensitive it reacts, the more susceptible it is to failure during operation. To meet both criteria at the same time, is realized by the repeated provision of the above so-called thresholds that have to be overcome, if an alarm 161 has to be actually caused.

Suitable values for the minimum of periods is the amount of at least five subsequent voltage periods. A suitable amount for the control of the active power, (calculated from current) and for the comparison of the active power (calculated from voltage), each with the previously measured resistance value, lies in a range of less than 5%, preferably less than 2%. A suitable value for the window or control window which the resistance difference has to leave for the case of failure, lies at ±2.5%. Here, it should be noted that the threshold (i.e. the window) must not be too large to miss or hide a case of failure, on the other hand it must not be chosen too small, to assume too often a case of failure, of which only few are real cases of failure, such as shown in FIG. 1 in area F.

Functional software interface (GUI, operating panel)

The GUI (Grafic User Interface) can be designed with several register cards 210. At the starting page 211 (see also FIG. 8), the following characteristics can be adjusted . . . .

For configuration 221 of the measuring system . . . .
Sampling rate, area 221a
Amount of values, area 221b
Time interval, area 221c, for the display and saving of the graph (in hours, adjusted are 24 h)
Alarm limits, area 222, plus/minus in percent, as the above-mentioned third threshold value, in form of eight windows
Activation/deactivation of data acquisition, area 223, per installation 10
Functional removal of individual heating zones from the alarm evaluation, area 224.

The information 200, defined with the tab 211 on the starting page, concerning an entire installation with in the example eight thermal installations PHOT-0400 to PHOT-1400, shall be picked out from the above abstract definition for a more precise one.

The measuring system is configured at 211 (in the sub-tab). The limits (the third threshold value) are configured or determined with sub-tab 222, i.e. according to +/−limits, such that the here adjusted limits of ±2.5% give a range for e.g. PHOT-0400, within which no warning or no alarm is given.

Without a separate tab, directly at the user surface, area 223 is located with graphically activable buttons or areas, where the eight above-mentioned installations are switched on as activated for data collection. In the lower area of the graphical display, the evaluation is located in the sub-tab 224, wherein each installation of PHOT-0400 to PHOT-1400 is displayed in the area 224a, together with all their zones, here five zones each (Bottom, CTR1, CTR2, CTR3 and Top).

This graphical tab card, activated with tab 211, thus has the configuration properties of the measuring system, the configuration of the limits, the alarm evaluation and an additional field activating the data acquisition at each of the various thermal installations.

Here, in a special way, all useful data for the configuration of the system are provided and visualized optically. Important criteria are the adjustment of the window sizes for the resistance differences in the individual installations, within which no warning occurs respectively. In addition, entire zones or even entire installations can be excluded from the warning by activation or deactivation in the field with tab 224. Such an evaluation makes it possible to survey a great variety of process data, recognizable at the sample rate 221a, the amount of the samples 221b and the given time interval, for which the measuring values are to be stored as graphs. Nevertheless, an overview is achieved that is functionally easy to understand, allowing the user to monitor the installation(s) and their cases of failure, make a preset and also to activate as well as to deactivate.

The following register cards 212, 212a, 212b, . . . (see FIG. 9) are related to the installations PHOT-0400, PHOT-0500 . . . and so on. On these, the currently determined data are shown and the resistance values are presented graphically. In the text field, alarm message 91, the case of alarm 90 appears in written form.

In register history 213 (see FIG. 10) it is possible to read the resistance values of the individual installations from the past.

The change in resistance (see FIG. 11) can also be observed over the time, since for each time interval the mean value is determined and stored.

Under a U-I-evaluation (see FIG. 12) the raw data of voltage and current can be observed in the case of failure.

The functional identification shall here be explained using FIG. 9 in the following tabs 212, 212a, 212b and so on. Each installation is displayed here more concretely and has a chart 232 for the display of the resistance curve over time. Here, only tab 212 shall be explained, in the same way the tabs 212a, 212b are developed and realized functionally. When the user leaves the starting page of tab 211, installation PHOT-400 is visually displayed when clicking on tab 212.

Three larger fields are visible, the actual process data (measuring data and calculated values) in field 230, alarm messages 90 in field 91 (currently no alarms are displayed, which means that the installation runs error-free), and for a better visual understanding, a chart of at least four resistance curves 232 over the time, wherein two resistances can be overlapping over the course of time, between 4.25 Ohm and 4.5 Ohm.

In the actual measuring window 230 provided in this installation PHOT-400, concerning the provided five zones (Bottom, CTR1, CTR2, CTR3 and Top), all physical quantities existing there are visible, the calculated resistance, the registered voltage, the measured current, the calculated active power. A visual notice, for example a LED-symbol, can symbolize whether an alarm is active, and the alarms that occurred before can additionally be displayed in a smaller window for each of the five zones.

The individualization of each thermal installation shown in the figure allows the user to comprehend very concretely in every detail what has happened during the process and to overlook in a very abstract way the superior measurements and other results of the process(es), to evaluate visually the displayed results and to be fast in doing so. Using the example of tab 212, multiplied by further seven installations PHOT-0500 to PHOT-1400 presented here, it becomes easily apparent what amounts of data have to be processed here in such a way that they can be easily grasped and evaluated by the user. Independent therefrom of course is the automatic evaluation of an alarm event, depending on the settings of the parameters at the starting page 211 of the GUI.

The configurations are concentrated on starting page 211. The installation results on the register cards 212, 212a, . . . with associated alarm message 90 for a respective installation and within the installation for all zones existing there, in the example five zones per installation 10 in the complete installation 100.

Optionally, also an alarm message of the thyristor unit 40 (as example of power switches) can be added to the alarms, not only the recording of a resistance coil being damaged.

The tabs 213 (FIGS. 10 and 11) as well as the UI-evaluation 214 (in FIG. 12) serve to control and to have a look in retrospect at a failure development. Often it is useful to have a second display and a second look at the exact development of an occurring error, often it is also helpful to analyze why an error was detected and how, and nonetheless it is useful also to analyze an accidentally reported alarm, why it was detected although it should not have been detected. All these tasks are supported by the records of the past (History, tab 213) and the records of the measurements of the resistance drift, how it behaves in long-time. For this purpose, e.g. according to FIG. 11, the mean value per day is registered, wherein the displayed scale of the x-axis between two vertical sections in the FIGS. 9, 10 and 11 respectively, is increasing continuously. While in FIG. 9 a scale of the x-axis is sub-divided with 2 min (for a respective installation in the tab 212, 212a, 212b), the history-display in tab 213 is already extended to 2 h per scale unit and the drift is scaled with two months over a still longer period of time.

The measuring data are continually compressed, thus allowing long-term conclusions and evaluations as well as short-term observations in the minute raster.

The outsourced data can be read, using field 235 (a text file is provided making these data available). Drift-data can be read as well, using field 236 as shown in FIG. 11, in each case with regard to the installation, function field 237. The reading of drift-data over a period longer than one day (the history-data of FIG. 10 display approximately one day with 24 hours) can be achieved with the raster of two months in FIG. 11 and the chart-drift-data 234′.

All fields described here are touch-sensitive or click-sensitive in order to initiate a respective action.

Monitoring and control are also supported by a record of the voltage curve, comparable to the resistance value with the activable field 240. The appearing voltage curve 241 is scaled over the amount of data samples at the x-axis.

It is apparent that the zero crossings are suppressed, as has been explained before, using FIG. 6b with function 121. One of these points is picked out with 241a. It is to be understood, that in the case of necessary four or five periods for the calculation of an value of the effective value of the voltage and a respective value of the current, significantly more data samples for voltage and current for the UI-evaluation are stored, i.e. permanently stored, than it is the case for the History 213 of the resistance value of all installations.

The FIGS. 13 and 14 show, as mentioned above, that an early detection of a winding contact was possible, called Event 1 in FIG. 13 and Event 2 in FIG. 14.

The proof is provided with the History and the respective tab 213, allowing a further subsequent and retrospect analysis of what has happened with the help of the above-described functional procedure of FIG. 10. A time grid of 2 h is assumed and displayed, such as shown in FIG. 10, wherein via the functional selection field 237 for the alarm case of FIG. 13 the installation PHOT-0900 is shown

For Event 2 in FIG. 14, the installation PHOT-1000 is chosen in the functional selection field 237, and in both displays a scale of 2 h per scale raster is used.

In a detail enlargement, the temporal range 300 is enlarged to 300′ in FIG. 13 to illustrate the beginning of the case of failure (a change in resistance of 7% occurs) at the time 310. The breaking of the resistance is shown at 320 after 5 h as an actual case of failure. The alarm generation in the case of a observed (imminent) actual case of failure, however, takes place earlier and is classified by the system as case of failure already before the actual failure causes a system breakdown (making the loaded charge useless).

In a comparable detail enlargement, the temporal range 300 is enlarged to 300″ at FIG. 14 to illustrate the beginning of the Event-2-case of failure (here, a change in resistance of 7% at time 310′ occurred as well). The breaking of the resistance is shown at 320′ after 3.5 h as a second actual case of failure. The alarm generation took place already 3.5 h before.

Proof of the Early Detection . . . .

Since the installation of the heater monitoring at the internal installations, is has been possible to demonstrate two events of an early detection of a winding contact (Event 1 and Event 2, shown in FIGS. 13 and 14). In both cases, there was a change in resistance of approx. 7% and approx. 3.5 h or 5 h respectively, a breakage of a winding occurred (a breakage of the heating coil in the thermal installation).

It was possible to save the production lots with the help of the alarm message(s) at the installations.

1. A method for monitoring a thermal device (100) for the accommodation and temperature control of waferlots or batches of wafers,
wherein a continuously provided measurement of a resistance value (R₁) of a resistance (1) in at least one heating zone (1′) of several heating zones (1′, 2′, 3′, 4′, 5′) of the thermal device (100) takes place;
a currently measured value (R₁(i)) of the resistance (1) in the associated heating zone (1′) is compared with a previously measured value (R₁(i−1)) of the same resistance (1);
a warning or an alarm (90) for the thermal device (100) is generated when a deviation (310, ΔR₁) is detected by the comparison of the two resistance values (R₁(i), R₁(i−1)) from the same heating zone (1′), before a failure of a complete heating zone (1′) of the thermal device (100) takes place.

2. The method according to claim 1, wherein the continuously provided measurement of the resistance is obtained from a plurality of measurements of voltage (21) and current (31) at the resistance (1) and respective calculation of the value (R₁) of the resistance (1).

3. The method according to claim 2, wherein the continuously provided measurement of the resistance value (R₁) provides a chronological sequence of the value (R₁ (i)) of the resistance (1), wherein the chronological sequence derives from an i-th sample value.

4. The method according to claim 1, wherein the generated warning or the generated alarm (90) for the thermal device leads to an exchange of the resistance (R₁) in the heating zone (1′).

5. The method according to claim 1, wherein the continuously provided measurement of the resistance value (R₁) or the resistance (1) comprises a measurement before the actual operation of the thermal device (100).

6. The method according to claim 1, wherein the deviation (ΔR₁) that is detected by the comparison of the two temporarily spaced resistance values, in the case of electrical contact (F₁) of adjoining sites (1.3, 1.4) of the heating coil as resistance (1) takes place before a current-interrupting breakage (320) of the heating coil as resistance (1).

7. The method according to claim 1, wherein the deviation (ΔR₁) that is detected by comparison of the two resistance values is less than 10% of the resistance value (R₁) of a healthy, undamaged heating coil (1).

8. The method according to claim 7, wherein the deviation that is detected by comparison of the two temporarily spaced resistance values, is less than 7% of the value of the healthy, undamaged heating coil (1).

9. The method according to claim 1, wherein a breakage of a heating coil (1) lies more than one hour after a detection of a deviation (ΔR₁) detected by the comparison of the two measured resistance values (R₁(i), R₁(i−1)).

10. The method according to claim 1, wherein the detected deviation (ΔR₁) is before a failure of the heating zone (1′) with an associated heating resistance as heating coil (1).

11. The method according to claim 1, wherein the respective resistance in the various heating zones (1′, 2′, 3′, 4′, 5′) is measured and compared continuously.

12. The method according to claim 1, wherein in various heating zones (1′, 2′, 3′, 4′, 5′) of several systems (100) the respective resistance is measured and compared continuously.

13. The method according to claim 1, wherein the continuously provided measurement is in operation even when the thermal device (100) or its heating zones (1′, 2′, . . . ) or one of its heating zones cool(s) down or is/are in cooling operation.

14. The method according to claim 1, wherein various thresholds are provided (122, 142, 151) that have to be overcome in the course of the measurement in order to conclude (151a) automatically from the measurements whether to generate an alarm (90, 61, 161).

15. The method according to claim 14, wherein:
(a) a minimum number of periods of the voltage supplying the respective resistance (1) have to be connected through in sequence by the associated power control (40), in particular thyristor control;
or
(b) active powers from the calculated resistance (149) and respectively from the measured voltage as well as from the measured current are calculated and compared;
or
(c) the detected and calculated resistance difference (ΔR₁) is subject to or exposed to a control window and the resistance difference has to leave the control window.

16. The method according to claim 15, wherein at least four periods have to be connected through, or the calculated active powers in comparison with each other are allowed to differ less than 2% or at least 2.5% of the calculated resistance difference (ΔR₁) must have been detected.

17. The method according to claim 1, wherein in order to obtain a clean RMS generation for current and voltage at the resistance or resistances, the zero crossings are filtered out and only negative half-waves are used for evaluation.

18. A screen display for the monitoring of several thermal systems (100) or for the execution of the method according to one of the above claims, comprising
(i) a configuration window area (211) for the display of technical parameters of the thermal systems (100) in the form of a first field (321) with segments (221a, 221b) for the configuration of sample rate and number of sample values, a second field (222) for specification of window sizes for calculated resistance values and a third field (224, 224a) for activation or deactivation of heating zones (1′, 2′, . . . ) in the thermal systems (100), and a fourth field (223) for the connection or deactivation of complete thermal systems;
(ii) a measuring and recording window area (212) for the display of technical measuring values of one of the thermal systems (100) in the form of at least three visibly arranged further fields (230, 232, 91), one for real or calculated measuring values (23a), wherein the calculated resistance value of each heating zone of this thermal system (100), one field (91) for alarm messages (90) and one field for the display of a time course of calculated resistance values (R₁(i)).

19. The screen display according to claim 18, wherein various measuring and recording window areas (212a, 212b) are provided, each being assigned to a thermal system (100).

20. A system comprising:
a thermal device (100);
a screen display; and
a monitoring device for the monitoring of thermally treated waferlots or charges of wafers; wherein:
a continuously provided measurement of a resistance value (R₁) of a resistance (1) in at least one heating zone (1′) of several heating zones (1′, 2′, 3′, 4′, 5′) of the thermal device (100);
a currently measured value (R₁(i)) of the resistance (1) in the associated heating zone (1′) is compared with a previously measured value (R₁(i−1)) of the same resistance (1); and
the monitoring device generates a temporary warning or an alarm (90) for the thermal device (100) when a deviation (310, ΔR₁) is detected by a comparison of the two resistance values (R₁(i); R₁(i−1)) from the same heating zone (1′) of the thermal device before a failure of a complete heating zone (1) in the thermal device (10) takes place.

21. The system according to claim 20, further comprising:
a calculating means; and
a comparator (54);
wherein the calculating means (140) calculates a currently measured value (R₁(i)) of the resistance (1) of the respective heating zone (1′), and the comparator compares the currently measured value to a previously measured value (R₁(i)) of the same resistance (1).

22. The system according to claim 21, wherein already when the comparator records a deviation (310, ΔR₁) of the two resistance values from the same heating zone (1′), a warning or an alarm (90) for the thermal device (100) is initiated or generated before a failure of one or the complete heating zone (1) of the thermal device (100).

23. The system according to claim 22, wherein the comparator (144, 54) is a subtractor.

24. The method according to claim 9, wherein the recorded deviation (ΔR₁) lies far before a failure of the heating zone (1′) with a related heating resistance as heating coil (1).
